(19) United States
(12) Patent Application Publication
(10) Pub. No.: US 2026/0194818 A1
(43) Pub. Date: Jul. 9, 2026

(54) PULSE WIDTH EXTENSION DEVICE, ALIGNMENT ADJUSTMENT METHOD, AND ELECTRONIC DEVICE MANUFACTURING METHOD

(71) Applicant: Gigaphoton Inc., Tochigi (JP)

(72) Inventor: Kohei KUSAYANAGI, Tochigi (JP)

(73) Assignee: Gigaphoton Inc., Tochigi (JP)

(21) Appl. No.: 19/407,772

(22) Filed: Dec. 3, 2025

(30) Foreign Application Priority Data
Jan. 6, 2025 (JP) 2025-001786

(51) Int. Cl. G03F 7/00

(52) U.S. Cl. CPC G03F 7/70025; G03F 7/70041; G03F 7/702; G03F 7/7085

(57) ABSTRACT

A pulse width extension device includes a beam splitter configured to split pulse laser light into loop light and through light and superimpose the loop light circulated through a loop optical path at least once on the through light, and a plurality of concave mirrors configuring the loop optical path. A total number of the concave mirrors is 4n, where n is an integer equal to or more than 1. A first concave mirror on which the loop light is incident firstly from the beam splitter and a second concave mirror on which the loop light is incident thirdly or in a 4n-1-th order from the beam splitter, among the plurality of concave mirrors, are arranged such that an angle of a reflection surface of each of the first concave mirror and the second concave mirror is capable of being adjusted with a position thereof fixed.

### CROSS-REFERENCE TO RELATED APPLICATIONS

The present application claims the benefit of Japanese Patent Application No. 2025-001786, filed on Jan. 6, 2025, the entire contents of which are hereby incorporated by reference.

### BACKGROUND

### 1. Technical Field

The present disclosure relates to a pulse width extension device, an alignment adjustment method, and an electronic device manufacturing method.

### 2. Related Art

Recently, in a semiconductor exposure apparatus, improvement in resolution has been desired for miniaturization and high integration of semiconductor integrated circuits. For this purpose, an exposure light source that outputs light having a shorter wavelength has been developed. For example, as a gas laser device for exposure, a KrF excimer laser device for outputting laser light having a wavelength of about 248 nm and an ArF excimer laser device for outputting laser light having a wavelength of about 193 nm are used.

The KrF excimer laser device and the ArF excimer laser device each have a large spectral line width of about 350 to 400 pm in natural oscillation light. Therefore, when a projection lens is formed of a material that transmits ultraviolet rays such as KrF laser light and ArF laser light, there is a case in which chromatic aberration occurs. As a result, the resolution may decrease. Then, a spectral line width of laser light output from the gas laser device needs to be line-narrowed to the extent that the chromatic aberration can be ignored. For this purpose, there is a case in which a line narrowing module (LNM) including a line narrowing element (etalon, grating, and the like) is provided in a laser resonator of the gas laser device to line-narrow a spectral line width. In the following, a gas laser device with a narrowed spectral line width is referred to as a line narrowing gas laser device.

### LIST OF DOCUMENTS

### Patent Documents

Patent Document 1: US Patent Application Publication No. 2023/0061530

Patent Document 2: US Patent Application Publication No. 2023/0066377

Patent Document 3: US Patent Application Publication No. 2024/0272444

Patent Document 4: US Patent Application Publication No. 2017/0365475

Patent Document 5: U.S. Pat. No. 10,629,438

### SUMMARY

A pulse width extension device according to an aspect of the present disclosure includes a beam splitter configured to split pulse laser light into loop light and through light and superimpose the loop light circulated through a loop optical path at least once on the through light, and a plurality of concave mirrors configuring the loop optical path. Here, a total number of the concave mirrors is 4n, where n is an integer equal to or more than 1. A first concave mirror on which the loop light is incident firstly from the beam splitter and a second concave mirror on which the loop light is incident thirdly or in a 4n-1-th order from the beam splitter, among the plurality of concave mirrors, are arranged such that an angle of a reflection surface of each of the first concave mirror and the second concave mirror is capable of being adjusted with a position thereof fixed.

An alignment adjustment method of a pulse width extension device according to an aspect of the present disclosure includes changing an angle of a reflection surface of a first concave mirror, and changing an angle of a reflection surface of a second concave mirror. Here, the pulse width extension device includes a beam splitter configured to split pulse laser light into loop light and through light and superimpose the loop light circulated through a loop optical path at least once on the through light, and a plurality of concave mirrors configuring the loop optical path. A total number of the concave mirrors is 4n, where n is an integer equal to or more than 1. The first concave mirror on which the loop light is incident firstly from the beam splitter and the second concave mirror on which the loop light is incident thirdly or in a 4n-1-th order from the beam splitter, among the plurality of concave mirrors, are arranged such that the angle of the reflection surface of each of the first concave mirror and the second concave mirror is capable of being adjusted with a position thereof fixed.

An electronic device manufacturing method according to an aspect of the present disclosure includes generating pulse laser light with a pulse width extended using a laser device, outputting the pulse laser light to an exposure apparatus, and exposing a photosensitive substrate to the pulse laser light in the exposure apparatus to manufacture an electronic device. Here, the laser device includes a laser oscillator configured to output the pulse laser light, and a pulse width extension device in which the pulse laser light having entered is output with the pulse width thereof extended. The pulse width extension device includes a beam splitter configured to split the pulse laser light into loop light and through light and superimpose the loop light circulated through a loop optical path at least once on the through light, and a plurality of concave mirrors configuring the loop optical path. A total number of the concave mirrors is 4n, where n is an integer equal to or more than 1. A first concave mirror on which the loop light is incident firstly from the beam splitter and a second concave mirror on which the loop light is incident thirdly or in a 4n-1-th order from the beam splitter, among the plurality of concave mirrors, are arranged such that an angle of a reflection surface of each of the first concave mirror and the second concave mirror is capable of being adjusted with a position thereof fixed.

### BRIEF DESCRIPTION OF THE DRAWINGS

Embodiments of the present disclosure will be described below merely as examples with reference to the accompanying drawings.

FIG. 1 is a front view schematically showing the configuration of a laser device according to a comparative example.

FIG. 2 is a view of an L-OPS viewed from a V-axis direction.

FIG. 3 is a view of the L-OPS viewed from obliquely above.

FIG. 4 is a diagram schematically showing a configuration example of a measurement device.

FIG. 5 is a diagram explaining alignment adjustment of a first loop optical path according to the comparative example.

FIG. 6 is a flowchart showing an example of overall flow of alignment adjustment operation according to the comparative example.

FIG. 7 is a flowchart showing details of the alignment adjustment according to the comparative example.

FIG. 8 is a diagram explaining the alignment adjustment of the first loop optical path according to an embodiment.

FIG. 9 is a flowchart showing details of the alignment adjustment according to the embodiment.

FIG. 10 is a diagram explaining the alignment adjustment of the first loop optical path according to a modification.

FIG. 11 is a flowchart showing details of the alignment adjustment according to the modification.

FIG. 12 is a table summarizing concave mirrors used for positioning adjustment and pointing adjustment in the embodiment and the modification.

FIG. 13 is a view of a holder viewing from a front side.

FIG. 14 is a view of the holder viewing from a rear side.

FIG. 15 is a view showing a modification of an angle adjustment device.

FIG. 16 is a front view of the holder.

FIG. 17 is a diagram schematically showing a configuration example of an exposure apparatus.

### DESCRIPTION OF EMBODIMENTS

### Contents

1. Comparative example
   1.1 Configuration
      1.1.1 Laser device
      1.1.2 Pulse width extension device
   1.2 Operation
   1.3 Alignment adjustment
   1.4 Problem
2. Embodiment
   2.1 Configuration
   2.2 Operation
   2.3 Alignment adjustment
   2.4 Effect
   2.5 Modification
3. Summarization
4. Holder
5. Electronic device manufacturing method

Hereinafter, embodiments of the present disclosure will be described in detail with reference to the drawings. The embodiments described below show some examples of the present disclosure and do not limit the contents of the present disclosure. Also, all configurations and operation described in the embodiments are not necessarily essential as configurations and operation of the present disclosure. Here, the same components are denoted by the same reference numeral, and duplicate description thereof is omitted.

### 1. Comparative Example

### 1.1 Configuration

### 1.1.1 Laser Device

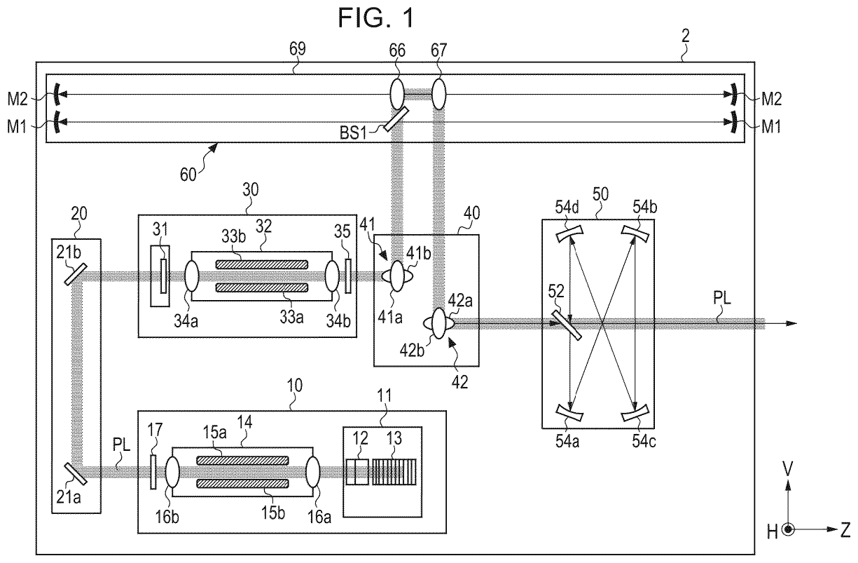

FIG. 1 schematically shows the configuration of a laser device 2 according to a comparative example. The comparative example of the present disclosure is an example recognized by the applicant as known only by the applicant, and is not a publicly known example admitted by the applicant.

In FIG. 1, the height direction of the laser device 2 is defined as a V-axis direction, the length direction thereof is defined as a Z-axis direction, and the depth direction is defined as an H-axis direction. For example, the V-axis direction is parallel to the gravity direction. Further, the Z-axis direction is parallel to an output direction of pulse laser light PL output from the laser device 2.

The laser device 2 is a line narrowing gas laser device including a master oscillator (MO) 10, an MO beam steering unit 20, a power oscillator (PO) 30, a PO beam steering unit 40, and an optical pulse stretcher (OPS) 50. The master oscillator 10 is an example of the “laser oscillator” according to the technology of the present disclosure.

Further, the laser device 2 includes a long optical pulse stretcher 60 (hereinafter, referred to as the “L-OPS 60”). In the present disclosure, the pulse width refers to the temporal width of a pulse. Further, the L-OPS 60 is an example of the “pulse width extension device” according to the technology of the present disclosure.

The master oscillator 10 includes a line narrowing module (LNM) 11, a chamber 14, and an output coupling mirror (Output Coupler: OC) 17.

The LNM 11 includes a prism beam expander 12 and a grating 13 for narrowing the spectral line width. The prism beam expander 12 and the grating 13 are arranged in the Littrow arrangement so that an incident angle and a diffraction angle coincide with each other.

The output coupling mirror 17 is a reflection mirror having a reflectance in the range of 40% to 60%. The output coupling mirror 17 and the LNM 11 are arranged to configure an optical resonator.

The chamber 14 is arranged on the optical path of the optical resonator. The chamber 14 includes a pair of discharge electrodes 15a, 15b and two windows 16a, 16b through which the pulse laser light PL passes. The chamber 14 contains an excimer laser gas. The excimer laser gas may include, for example, an Ar gas or a Kr gas as a rare gas, an F₂ gas as a halogen gas, and an Ne gas as a buffer gas.

The MO beam steering unit 20 includes a high reflection mirror 21a and a high reflection mirror 21b. The high reflection mirror 21a and the high reflection mirror 21b are arranged such that the pulse laser light PL output from the master oscillator 10 enters the power oscillator 30. The high reflection mirror of the present disclosure is a planar mirror with a high reflection film formed on a surface of a substrate formed of, for example, synthetic quartz or calcium fluoride (CaF₂). The high reflection film is a dielectric multilayer film, for example, a film containing fluoride.

The power oscillator 30 includes a rear mirror 31, a chamber 32, and an output coupling mirror 35. The rear mirror 31 and the output coupling mirror 35 are arranged to configure an optical resonator.

The chamber 32 is arranged on the optical path of the optical resonator. The chamber 32 may have a configuration similar to that of the chamber 14 of the master oscillator 10. That is, the chamber 32 includes a pair of discharge electrodes 33a, 33b and two windows 34a, 34b through which the pulse laser light PL passes. The chamber 32 contains the excimer laser gas.

The rear mirror 31 is a reflection mirror having a reflectance in the range of 50% to 90%. The output coupling mirror 35 is a reflection mirror having a reflectance in the range of 10% to 30%.

The PO beam steering unit 40 includes a first steering unit 41 and a second steering unit 42 for exchanging light with the L-OPS 60.

The first steering unit 41 includes a high reflection mirror 41a and a high reflection mirror 41b. The high reflection mirror 41a is arranged such that the pulse laser light output from the power oscillator 30 is reflected to be incident on the high reflection mirror 41b. The high reflection mirror 41b is arranged such that the pulse laser light PL reflected by the high reflection mirror 41a is reflected to enter the L-OPS 60.

The second steering unit 42 includes a high reflection mirror 42a and a high reflection mirror 42b. The high reflection mirror 42a is arranged such that the pulse laser light output from the L-OPS 60 is reflected to be incident on the high reflection mirror 42b. The high reflection mirror 42b is arranged such that the pulse laser light PL reflected by the high reflection mirror 42a is reflected to enter the OPS 50.

As will be described in detail later, the L-OPS 60 includes at least one beam splitter and a plurality of high reflection mirrors. The L-OPS 60 is arranged at a ceiling side part of the laser device 2.

The OPS 50 includes a beam splitter 52 and four concave mirrors 54a to 54d. The beam splitter 52 is arranged on the optical path of the pulse laser light PL output from the PO beam steering unit 40. The beam splitter 52 is a partial reflection mirror that transmits a part of the incident pulse laser light PL and reflects the other part thereof. The reflectance of the beam splitter 52 is preferably in the range of 40% to 70%, more preferably about 60%.

The four concave mirrors 54a to 54d configure a loop optical path through which a part of the pulse laser light PL having entered from the PO beam steering unit 40 and reflected by the beam splitter 52 is circulated and returned to the beam splitter 52. A part of the pulse laser light PL having entered from the PO beam steering unit 40 and transmitted through the beam splitter 52 is superimposed on a part of the pulse laser light PL having circulated through the loop optical path at least once and reflected by the beam splitter 52, and is output from the OPS 50.

The OPS 50 is arranged at the last stage of the laser device 2, and outputs the pulse laser light PL having the pulse width extended from the laser device 2.

Here, the OPS 50 is only required to include a beam splitter and a plurality of high reflection mirrors.

The laser device 2 may be covered with a cover panel (not shown) that can be removed for maintenance or the like.

### 1.1.2 Pulse Width Extension Device

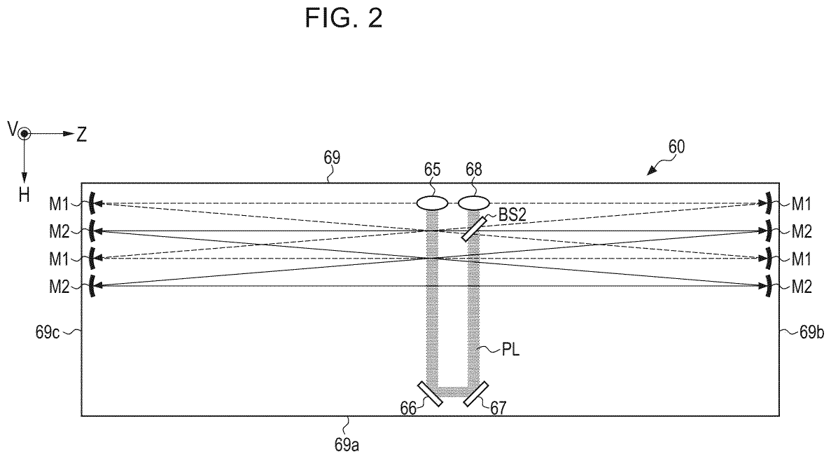

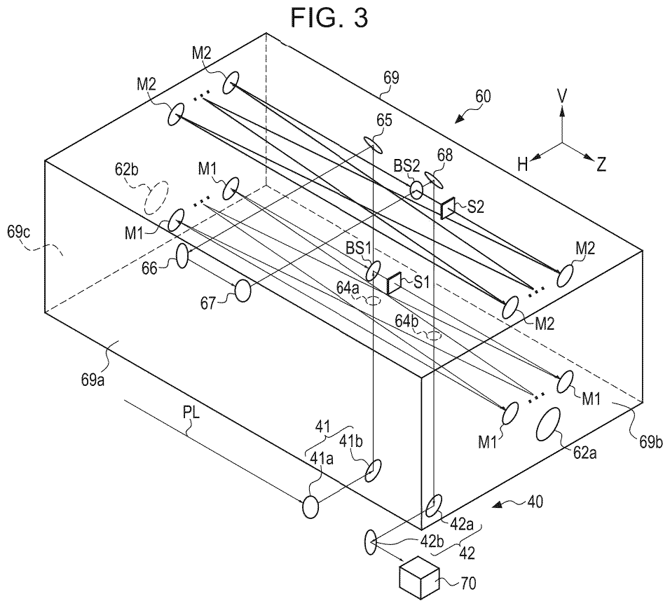

Next, the configuration of a pulse width extension device according to the comparative example will be described. FIG. 2 is a view of the L-OPS 60 viewed from the V-axis direction. FIG. 3 is a view of the L-OPS 60 viewed obliquely from above.

The L-OPS 60 includes a beam splitter BS1, a plurality of concave mirrors M1 configuring a first loop optical path, a beam splitter BS2, and a plurality of concave mirrors M2 configuring a second loop optical path. The L-OPS 60 is accommodated in a housing 69.

The first loop optical path is a 4f optical system configured of 4n pieces of the concave mirrors M1. The second loop optical path is a 4f optical system configured of 4n pieces of the concave mirrors M2. In the present disclosure, the 4f optical system refers to an optical system in which the optical path length thereof is 4n times of the focal length. Here, n is an integer equal to or more than 1. The total number of the concave mirrors M1 configuring the first loop optical path may be different from the total number of the concave mirrors M2 configuring the second loop optical path. The number of loop optical paths in the L-OPS 60 is not limited to 2, and may be 1 or 3 or more.

The housing 69 is a rectangular box body whose longitudinal direction is the Z-axis direction. The housing 69 has a front cover 69a and a pair of side covers 69b, 69c. The front cover 69a is provided on one of two surfaces facing in the H-axis direction and is opened and closed during maintenance. The pair of side covers 69b, 69c are arranged on two surfaces facing each other in the Z-axis direction. The inside of the housing 69 is purged with a purge gas which is an inert gas. For this purpose, a purge gas supply source (not shown) may be connected to the housing 69.

Further, on the bottom surface of the housing 69, an opening 64a for causing the pulse laser light PL output from the first steering unit 41 to enter the housing 69 and an opening 64b for outputting the pulse laser light PL toward the second steering unit 42 are provided. The openings 64a, 64b are connected to optical path pipes (not shown) purged with the purge gas.

The beam splitter BS1 is arranged on the optical path of the pulse laser light PL output from the first steering unit 41. The beam splitter BS1 is a partial reflection mirror that transmits a part of the incident pulse laser light PL and reflects the other part thereof. The reflectance of the beam splitter BS1 is preferably in the range of 40% to 70%, more preferably about 60%.

The plurality of concave mirrors M1 are arranged so that a part of the pulse laser light PL having entered from the first steering unit 41 through the opening 64a and reflected by the beam splitter BS1 is circulated and returned to the beam splitter BS1. A part of the pulse laser light PL having entered from the first steering unit 41 and transmitted through the beam splitter BS1 is superimposed on a part of the pulse laser light PL having circulated through the first loop optical path at least once and reflected by the beam splitter BS1, and is output from the high reflection mirror 65.

The high reflection mirror 65 is arranged such that the pulse laser light PL whose pulse width is extended by the first loop optical path is reflected to be incident on the high reflection mirror 66. The high reflection mirror 66 is arranged such that the pulse laser light PL reflected by the high reflection mirror 65 is reflected to be incident on the high reflection mirror 67. The high reflection mirror 67 is arranged such that the pulse laser light PL reflected by the high reflection mirror 66 is reflected to be incident on the beam splitter BS2.

The beam splitter BS2 is arranged on the optical path of the pulse laser light PL reflected by the high reflection mirror 67. The beam splitter BS2 is a partial reflection mirror that transmits a part of the incident pulse laser light PL and reflects the other part thereof. The reflectance of the beam splitter BS2 is preferably in the range of 40% to 70%, more preferably about 60%.

The plurality of concave mirrors M2 are arranged such that a part of the pulse laser light PL having entered from the high reflection mirror 67 and reflected by the beam splitter BS2 is circulated and returned to the beam splitter BS2. A part of the pulse laser light PL having entered from the high reflection mirror 67 and transmitted through the beam splitter BS2 is superimposed on a part of the pulse laser light PL having circulated through the second loop optical path at least once and reflected by the beam splitter BS2, and is output toward the high reflection mirror 68.

The high reflection mirror 68 is arranged such that the pulse laser light PL whose pulse width is further extended by the second loop optical path is reflected to be incident on the high reflection mirror 42a of the second steering unit 42 through the opening 64b.

The high reflection mirrors 66, 67 are arranged on the front cover 69a side of the housing 69, and the high reflection mirrors 65, 68 are arranged on the side opposite to the front cover 69a. Accordingly, the optical path between the high reflection mirror 65 and the first steering unit 41 and the optical path between the high reflection mirror 68 and the second steering unit 42 are arranged at the side opposite to the front cover 69a.

The plurality of concave mirrors M1 and the plurality of concave mirrors M2 are arranged at both ends in the Z-axis direction, which is the longitudinal direction of the housing 69, so that the first loop optical path and the second loop optical path overlap each other in the V-axis direction. A half of the plurality of concave mirrors M1 is arranged on the side cover 69b side, and the other half thereof is arranged on the side cover 69c side. A half of the plurality of concave mirrors M2 is arranged on the side cover 69b side, and the other half thereof is arranged on the side cover 69c side.

Further, each of the plurality of concave mirrors M1 is held by a holder (not shown). Each of the plurality of concave mirrors M2 is held by a holder (not shown). The side cover 69b is formed with one or more holes 62a to be used for adjusting alignment of the first loop optical path and the second loop optical path. Similarly, the side cover 69c is formed with one or more holes 62b to be used for adjusting alignment of the first loop optical path and the second loop optical path.

A shutter S1 is arranged between the beam splitter BS1 and the concave mirror M1 on which the pulse laser light PL reflected by the beam splitter BS1 is firstly incident. A shutter S2 is arranged between the beam splitter BS2 and the concave mirror M2 on which the pulse laser light PL reflected by the beam splitter BS2 is firstly incident. The shutter S1 is opened and closed when adjusting the alignment of the first loop optical path. The shutter S2 is opened and closed when adjusting the alignment of the second loop optical path.

In addition, a measurement device 70 capable of measuring positioning and pointing of the pulse laser light PL can be installed on the optical path of the pulse laser light PL output from the L-OPS 60. The measurement device 70 is capable of being inserted on and removed from the optical path. In the present disclosure, positioning refers to the position of the optical axis of the pulse laser light PL with respect to the ideal optical axis. Pointing refers to the angle of the optical axis of the pulse laser light PL with respect to the ideal optical axis.

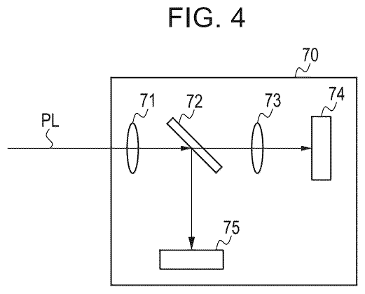

FIG. 4 schematically shows a configuration example of the measurement device 70. The measurement device 70 includes a lens 71, a beam splitter 72, a lens 73, an optical sensor 74, and an optical sensor 75. The lens 71 is arranged on the optical path of the pulse laser light PL that enters the measurement device 70. The beam splitter 72 is arranged on the optical path of the pulse laser light PL transmitted through the lens 71. The beam splitter 72 is a partial reflection mirror that transmits a part of the incident pulse laser light PL and reflects the other part thereof.

The lens 73 is arranged on the optical path of the pulse laser light PL transmitted through the beam splitter 72. The optical sensor 74 is arranged on the optical path of the pulse laser light PL transmitted through the lens 73. The lens 73 configures a transfer optical system together with the lens 71, and transfers an image of the pulse laser light PL entering the measurement device 70 to a light receiving surface of the optical sensor 74. The position of the beam spot on the light receiving surface of the optical sensor 74 corresponds to the position of the optical axis of the pulse laser light PL entering the measurement device 70, that is, the positioning.

The optical sensor 75 is arranged on the optical path of the pulse laser light PL reflected by the beam splitter 72. The lens 71 forms an image of the pulse laser light PL reflected by the beam splitter 72 on the light receiving surface of the optical sensor 75. The position of the beam spot on the light receiving surface of the optical sensor 75 corresponds to the angle of the optical axis of the pulse laser light PL entering the measurement device 70, that is, the pointing.

Here, a display (not shown) is built in or connected to the measurement device 70, and the operator performing the alignment adjustment can confirm the beam spot position on the light receiving surface of the optical sensor 74 and the beam spot position on the light receiving surface of the optical sensor 75 using the display.

### 1.2 Operation

Next, operation of the laser device 2 according to the comparative example will be described. When discharge occurs in the chamber 14 of the master oscillator 10, the laser gas is excited, and the pulse laser light PL line-narrowed by the optical resonator configured by the output coupling mirror 17 and the LNM 11 is output from the output coupling mirror 17. The pulse laser light PL is incident on the rear mirror 31 of the power oscillator 30 as seed light by the MO beam steering unit 20.

Discharge occurs in the chamber 32 in synchronization with the timing when the seed light transmitted through the rear mirror 31 enters. As a result, the laser gas is excited, the seed light is amplified by the Fabry-Perot optical resonator configured by the output coupling mirror 35 and the rear mirror 31, and the amplified pulse laser light PL is output from the output coupling mirror 35. The pulse laser light PL output from the output coupling mirror 35 enters the PO beam steering unit 40, and enters the L-OPS 60 with the travel direction thereof changed by the first steering unit 41.

The pulse laser light PL having entered the L-OPS 60 is extended in pulse width and returns to the PO beam steering unit 40, and enters the OPS 50 with the travel direction thereof changed by the second steering unit 42.

The pulse width of the pulse laser light PL having entered the OPS 50 is further extended, and the pulse laser light PL is output from the laser device 2. Here, the pulse laser light PL may be output from the laser device 2 via a monitor module (not shown) that measures the pulse energy, the spectral line width, the wavelength, or the like. The pulse laser light PL output from the laser device 2 enters an external apparatus such as an exposure apparatus.

By extending the pulse width of the pulse laser light PL by the L-OPS 60 and the OPS 50, the coherence is reduced. This suppresses occurrence of speckle. Speckle is light and dark spots caused by interference when pulse laser light is scattered in a random medium.

### 1.3 Alignment Adjustment

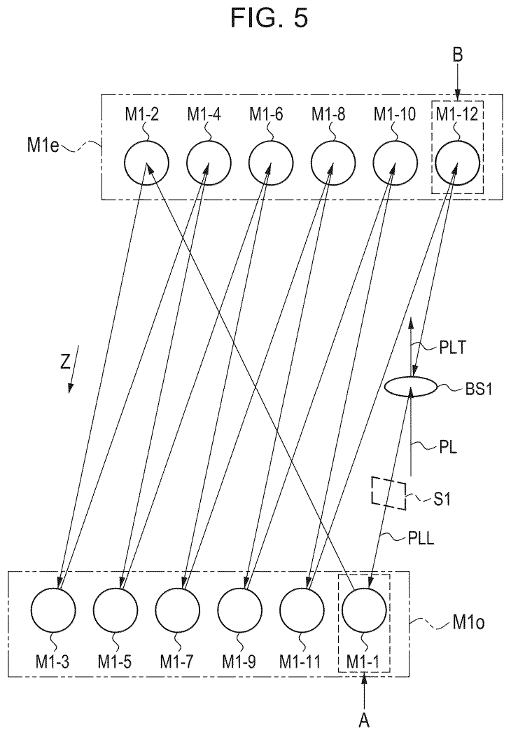

Next, alignment adjustment of the optical axis in the L-OPS 60 will be described. FIG. 5 shows the alignment adjustment of the first loop optical path according to the comparative example. As shown in FIG. 5, the beam splitter BS1 splits the pulse laser light PL having entered the L-OPS 60 into loop light PLL and through light PLT. Specifically, the beam splitter BS1 reflects a part of the pulse laser light PL to generate the loop light PLL, and transmits another part of the pulse laser light PL to generate the through light PLT. The loop light PLL is circulated through the first loop optical path at least once and superimposed on the through light PLT.

In the example shown in FIG. 5, the total number of concave mirrors M1 configuring the first loop optical path is 12, that is, n=3. Further, the twelve concave mirrors M1 are distinguished from one another in order along the circulation path of the loop light PLL from the beam splitter BS1 by giving a sign M1-1, M1-2, . . . , M1-12. That is, the concave mirror M1-k is the concave mirror M1 on which the loop light PLL is incident in the k-th order from the beam splitter BS1.

The plurality of concave mirrors M1-1, M1-3, . . . , M1-11 on which the loop light PLL is incident each in the odd-numbered orders from the beam splitter BS1 are referred to as a first concave mirror group M1o. Further, the plurality of concave mirrors M1-2, M1-4, . . . , M1-12 on which the loop light PLL is incident each in the even-numbered orders from the beam splitter BS1 are referred to as a second concave mirror group M1e. The first concave mirror group M1o and the second concave mirror group M1e are arranged at positions facing each other. The first concave mirror group M1o is arranged on the side cover 69b side, which is the output side of the pulse laser light PL from the L-OPS 60. The second concave mirror group M1e is arranged on the side cover 69c side opposite to the output side.

The loop light PLL circulated through the first loop optical path and reflected by the beam splitter BS1 is superimposed on the through light PLT. When misalignment occurs on the first loop optical path, the alignment needs to be adjusted so that the optical axis of the loop light PLL to be superimposed coincides with the optical axis of the through light PLT. The misalignment of the first loop optical path is caused by tolerances of the optical system, replacement of optical elements in the first loop optical path, change of the optical axis of the pulse laser light PL entering the L-OPS 60, and the like.

The alignment adjustment is performed by positioning adjustment and pointing adjustment. Reference sign A in FIG. 5 denotes the concave mirror M1 to be used for the positioning adjustment. Reference numeral B denotes the concave mirror M1 to be used for the pointing adjustment. In the comparative example, the positioning adjustment is performed by adjusting the angle of the reflection surface of the concave mirror M1-1, and the pointing adjustment is performed by adjusting the angle of the reflection surface of the concave mirror M1-12.

Since the positioning adjustment is preferably performed by using the concave mirror M1 having the longest optical path length from the output position of the loop light PLL from the first loop optical path, the concave mirror M1-1 is selected. On the other hand, since the pointing adjustment is preferably performed using the concave mirror M1 that lastly reflects the loop light PLL in the first loop optical path, the concave mirror M1-12 is selected. This is because the concave mirror M1-12 can directly change the angle of the loop light PLL output from the first loop optical path without being affected by other concave mirrors M1.

Since the alignment adjustment of the second loop optical path is similar to the alignment adjustment of the first loop optical path, description thereof will be omitted. The alignment adjustment described below will also be described by taking only the alignment adjustment of the first loop optical path as an example.

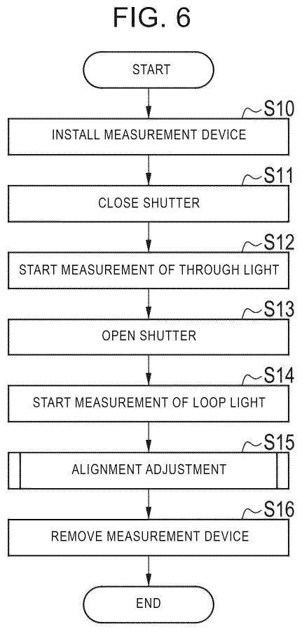

FIG. 6 shows an example of the overall flow of alignment adjustment operation according to the comparative example. First, an operator installs the measurement device 70 on the optical path of the pulse laser light PL output from the L-OPS 60 (step S10). The position at which the measurement device 70 is installed is preferably as far as possible from the L-OPS 60. Next, the operator closes the shutters S1, S2 (step S11). Then, the operator starts measurement of the through light PLT output from the L-OPS 60 by operating the laser device 2 (step S12).

Next, the operator opens the shutter S1 (step S13) and starts measurement of the loop light PLL output from the first loop optical path (step S14). When misalignment occurs on the first loop optical path, two beam spots of the through light PLT and the loop light PLL appear on the light receiving surface of the optical sensor 74 and the light receiving surface of the optical sensor 75.

The operator performs the alignment adjustment so that the two beam spots of the through light PLT and the loop light PLL overlap each other (step S15). The operator performs the alignment adjustment similarly on the second loop optical path after the alignment adjustment on the first loop optical path.

Thereafter, the operator stops the operation of the laser device 2 and removes the measurement device 70 (step S16).

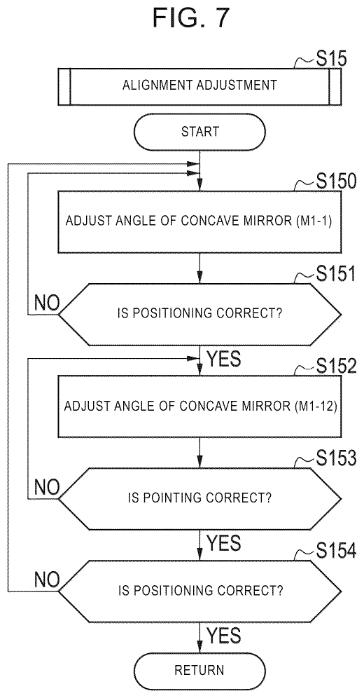

FIG. 7 shows details of the alignment adjustment operation (step S15) according to the comparative example. In step S15, first, the operator adjusts the angle of the reflection surface of the concave mirror M1-1 so that the two beam spots overlap each other on the light receiving surface of the optical sensor 74 (step S150). Specifically, the operator adjusts the angle of the reflection surface of the concave mirror M1-1 by operating an angle adjustment device of a holder holding the concave mirror M1-1 as passing an operation member such as a hexagonal wrench through the hole 62a of the side cover 69b.

Next, the operator determines whether or not the two beam spots overlap each other on the light receiving surface of the optical sensor 74, that is, whether or not the positioning is correct (step S151). When the positioning is not correct (step S151: NO), the operator performs step S150 again.

On the other hand, when the positioning is correct (step S151: YES), the operator adjusts the angle of the reflection surface of the concave mirror M1-12 so that the two beam spots overlap each other on the light receiving surface of the optical sensor 75 (step S152). Specifically, the operator adjusts the angle of the reflection surface of the concave mirror M1-12 by operating an angle adjustment device of a holder holding the concave mirror M1-12 as passing an operation member through the hole 62b of the side cover 69c.

Next, the operator determines whether or not the two beam spots overlap each other on the light receiving surface of the optical sensor 75, that is, whether or not the pointing is correct (step S153). When the pointing is not correct (step S153: NO), the operator performs step S152 again.

On the other hand, when the pointing is correct (step S153: YES), the operator determines again whether or not the positioning is correct (step S154). When the positioning is not correct (step S154: NO), the operator performs step S150 again.

On the other hand, when the positioning is correct (step S154: YES), the operator ends the alignment adjustment of the first loop optical path.

### 1.4 Problem

The alignment adjustment described above is usually performed by a single operator at the time of installation or maintenance of the laser device 2. Since the L-OPS 60 is long in the Z direction, the operator needs to adjust the concave mirror M1-1 and the concave mirror M1-12 having a large opposing distance therebetween. The opposing distance is, for example, in the order of 2.5 to 3 m and exceeds a span of both hands of the operator. Therefore, the operator needs to repeatedly move back and forth between the side cover 69b side and the side cover 69c side until the alignment adjustment is completed, and it takes a long time to complete the alignment adjustment.

Therefore, the present disclosure provides a pulse width extension device and an alignment adjustment method that enable completion of alignment adjustment in a short time.

### 2. Embodiment

The laser device 2 according to an embodiment of the present disclosure will be described. Any component same as that described above is denoted by an identical reference sign, and duplicate description thereof is omitted unless specific description is needed.

### 2.1 Configuration

The laser device 2 according to the embodiment has a configuration similar to that of the laser device 2 according to the comparative example except for the L-OPS 60.

The L-OPS 60 according to the embodiment has basically a similar configuration as the L-OPS 60 according to the comparative example shown in FIG. 3 except that the concave mirrors M1, M2 on which the angle adjustment of the reflection surface is performed at the time of the alignment adjustment differ.

### 2.2 Operation

Operation of the laser device 2 according to the present embodiment is similar to that of the laser device 2 according to the comparative example.

### 2.3 Alignment Adjustment

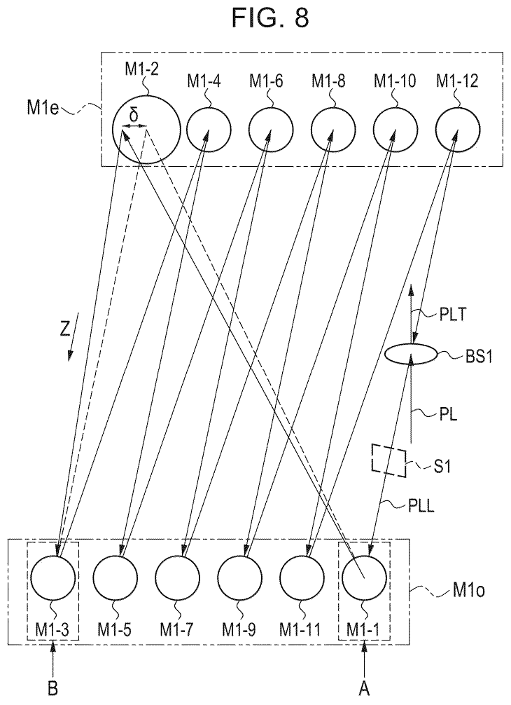

Alignment adjustment of the optical axis in the L-OPS 60 according to the embodiment will be described. FIG. 8 shows the alignment adjustment of the first loop optical path according to the embodiment. In the present embodiment, the L-OPS 60 is configured to be capable of performing the alignment adjustment by adjusting the angle of each of the reflection surface of the concave mirror M1-1 and the reflection surface of the concave mirror M1-3 included in the first concave mirror group M1o. Specifically, in the present embodiment, the positioning adjustment is performed by adjusting the angle of the reflection surface of the concave mirror M1-1, and the pointing adjustment is performed by adjusting the angle of the reflection surface of the concave mirror M1-3.

The concave mirror M1-1 is the concave mirror M1 on which the loop light PLL is firstly incident from the beam splitter BS1, and corresponds to the “first concave mirror” according to the technology of the present disclosure. The concave mirror M1-3 is the concave mirror M1 on which the loop light PLL is thirdly incident from the beam splitter BS1, and corresponds to the “second concave mirror” according to the technology of the present disclosure.

Since the alignment adjustment of the second loop optical path is similar to the alignment adjustment of the first loop optical path, description thereof will be omitted. The alignment adjustment described below will also be described by taking only the alignment adjustment of the first loop optical path as an example.

The overall flow of the alignment adjustment operation according to the present embodiment is similar to that according to the comparative example except for the alignment adjustment (step S15) shown in FIG. 6.

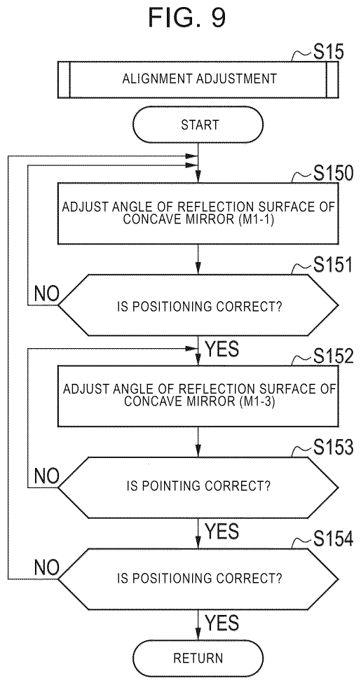

FIG. 9 shows details of the alignment adjustment according to the embodiment. The alignment adjustment according to the present embodiment differs from that according to the comparative example only in that, in step S152, the angle of the reflection surface of the concave mirror M1-3 is adjusted instead of the concave mirror M1-12.

The operator adjusts the angle of the reflection surface of each of the concave mirror M1-1 and the concave mirror M1-3 by operating the angle adjustment device of the holder as passing the operation member through the hole 62a of the side cover 69b.

In the present embodiment, the pointing adjustment is performed by using the concave mirror M1-3 after the positioning adjustment is performed by using the concave mirror M1-1, but the order of the positioning adjustment and the pointing adjustment may be reverse.

In the present embodiment, it is preferable that the area of the reflection surface of the concave mirror M1-2 on which the loop light PLL split by the beam splitter BS1 is secondly incident is larger than the area of the reflection surface of the concave mirror M1-1. Specifically, the clear aperture of the concave mirror M1-2 is preferably larger than the clear aperture of the concave mirror M1-1. In the present disclosure, the clear aperture refers to an effective aperture of the reflective surface.

This is because, in the present embodiment, the positioning adjustment is performed by using the concave mirror M1-1 and the pointing adjustment is performed by using the concave mirror M1-3, so that a deviation amount δ of the incident position of the loop light PLL on the concave mirror M1-2 from the center is larger than that in the comparative example. However, in the present embodiment, the concave mirror M1 in which the deviation amount δ increases is limited to only the concave mirror M1-2. For example, when the opposing distance between the first concave mirror group M1o and the second concave mirror group M1e is 3 m, the deviation amount δ in the concave mirror M1-2 is about 4 mm. It is preferable that the area of the reflection surface of the concave mirror M1-2 is larger than the area of the reflection surface of other concave mirrors M1 so that the clear aperture diameter can cover the deviation amount δ.

Since the first loop optical path is the 4f optical system, the incident position of the loop light PLL on the concave mirror M1-1 is transferred to the incident position of the loop light PLL on each of the concave mirrors M1-3, M1-5, . . . , M1-11 included in the first concave mirror group M1o other than the concave mirror M1-1. Therefore, the deviation amount δ is small in any of the concave mirrors M1-3, M1-5, . . . , M1-11. Accordingly, the area of the reflection surfaces of the concave mirrors M1-3, M1-5, . . . , M1-11 may be the same as that of the concave mirror M1-1.

Further, since the incident position of the loop light PLL in each of the concave mirrors M1-4, M1-6, . . . , M1-12 other than the concave mirror M1-2 included in the second concave mirror group M1e is near the center of its reflection surface by adjusting the angle of the concave mirror M1-3, the area of each reflection surface may be the same as that of the concave mirror M1-1.

Since the beam cross section of the loop light PLL is rectangular, the clear aperture can be effectively used if the reflection surface of the concave mirror M1 is rectangular. However, from the viewpoint of cost, it is preferable to use a concave mirror having a generally used circular reflection surface as the concave mirror M1.

### 2.4 Effect

In the present embodiment, the alignment adjustment is performed by using the concave mirror M1-1 and the concave mirror M1-3 both included in the first concave mirror group M1o on the side cover 69b side. Therefore, the operator does not need to repeatedly move back and forth between the side cover 69b side and the side cover 69c side until the alignment adjustment is completed, and the alignment adjustment can be completed in a short time.

Further, in the present embodiment, since the concave mirror M1 in which the deviation amount δ increases is limited to only the concave mirror M1-2, only the reflective surface of the concave mirror M1-2 among the plurality of concave mirrors M1 configuring the first loop optical path needs to be increased in area, so that the cost can be suppressed. This is because, in general, the larger the clear aperture is, the higher the price of the concave mirror is.

It is also conceivable to perform the alignment adjustment by using two concave mirrors M1 included in the second concave mirror group M1e on the side cover 69c side. However, in this case, the deviation amount δ in the second concave mirror group M1e becomes larger than the deviation amount δ in the first concave mirror group M1o. Since the clear aperture diameter is required to be increased as the deviation amount δ becomes larger resulting in higher cost, it is preferable to perform the alignment adjustment by using two concave mirrors M1 included in the first concave mirror group M1o.

### 2.5 Modification

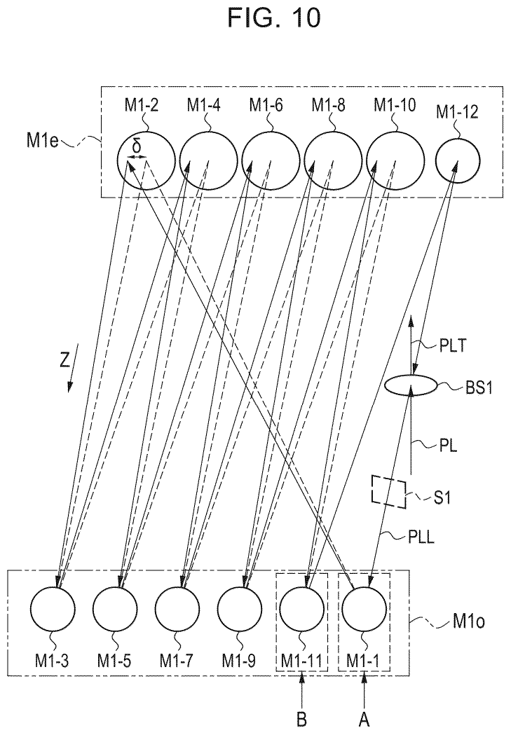

Next, a modification of the above embodiment will be described. FIG. 10 shows the alignment adjustment of the first loop optical path according to the modification. In the present modification, the L-OPS 60 is configured to be capable of performing the alignment adjustment by adjusting the angle of each of the reflection surface of the concave mirror M1-1 and the reflection surface of the concave mirror M1-11 included in the first concave mirror group M1o. Specifically, in the present embodiment, the positioning adjustment is performed by adjusting the angle of the reflection surface of the concave mirror M1-1, and the pointing adjustment is performed by adjusting the angle of the reflection surface of the concave mirror M1-11.

The concave mirror M1-1 is the concave mirror M1 on which the loop light PLL is firstly incident from the beam splitter BS1, and corresponds to the “first concave mirror” according to the technology of the present disclosure. The concave mirror M1-11 is the concave mirror M1 on which the loop light PLL is incident secondly to the last from the beam splitter BS1, and corresponds to the “second concave mirror” according to the technology of the present disclosure.

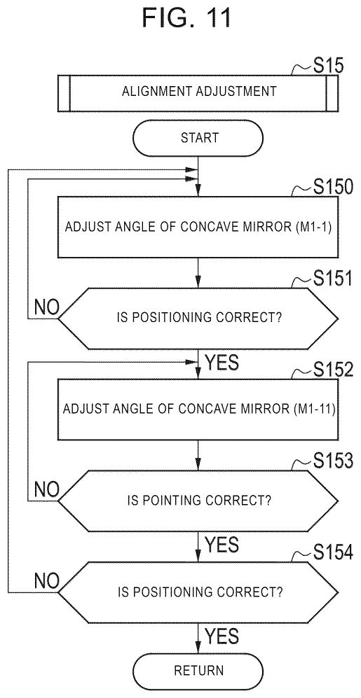

FIG. 11 shows details of the alignment adjustment operation according to the modification. The alignment adjustment according to the present modification differs from that according to the above embodiment only in that, in step S152, the angle of the reflection surface of the concave mirror M1-11 is adjusted instead of the concave mirror M1-3.

The operator adjusts the angle of the reflection surface of each of the concave mirror M1-1 and the concave mirror M1-11 by operating the angle adjustment device of the holder as passing the operation member through the hole 62a of the side cover 69b.

In the pointing adjustment, among the plurality of concave mirrors M1 included in the first concave mirror group M1o, the required adjustment angle becomes smaller as the adjustment is performed by using the concave mirror M1 close to the concave mirror M1-12 on which the loop light PLL is lastly incident in the first loop optical path. Therefore, in the present modification, the pointing adjustment is performed by using the concave mirror M1-11.

In the present modification, among the plurality of concave mirrors M1 included in the second concave mirror group M1e, the area of each of the reflection surfaces of the concave mirrors M1-2, M1-4, . . . , M1-10 other than the concave mirror M1-12 on which the loop light PLL is lastly incident in the first loop optical path is preferably larger than the area of the reflection surface of the concave mirror M1-1. Specifically, the clear aperture of each of the concave mirrors M1-2, M1-4, . . . , M1-10 is preferably larger than the clear aperture of the concave mirror M1-1.

This is because, in the present modification, the positioning adjustment is performed by using the concave mirror M1-1 and the pointing adjustment is performed by using the concave mirror M1-11, so that the deviation δ in each of the concave mirrors M1-2, M1-4, . . . , M1-10 becomes larger than that in the comparative example. For example, when the opposing distance between the first concave mirror group M1o and the second concave mirror group M1e is 3 m, the deviation amount δ in the concave mirror M1-2 is about 2 mm. It is preferable that each of the reflection surfaces of the concave mirrors M1-2, M1-4, . . . , M1-10 is larger than the reflection surface of other concave mirrors M1 so that the clear aperture diameter can cover the deviation amount δ. However, in the present modification, since the deviation amount δ is smaller than that in the above embodiment, the clear aperture diameter of each of the reflection surfaces of the concave mirrors M1-2, M1-4, . . . , M1-10 may be smaller than that of the concave mirror M1-2 of the above embodiment.

Other configurations and the alignment adjustment method of the L-OPS 60 according to the present modification are similar to those according to the above embodiment.

In the present modification, since the deviation amount δ is smaller than that in the above embodiment, the alignment adjustment can be completed in a short time.

### 3. Summarization

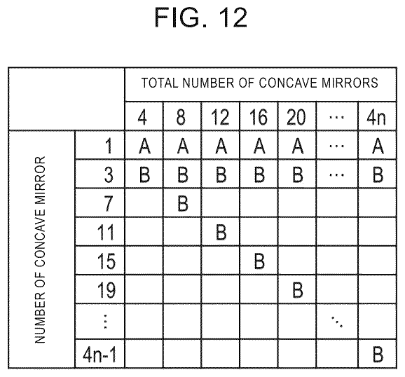

FIG. 12 summarizes the concave mirrors M1 used for the positioning adjustment and the pointing adjustment in the embodiment and the modification. The total number of the concave mirrors M1 is 4n. In the above embodiment, regardless of the total number of concave mirrors M1, the first concave mirror M1-1 is used for the positioning adjustment and the third concave mirror M1-3 is used for the pointing adjustment. In the above modification, the first concave mirror M1-1 is used for the positioning adjustment, and the 4n-1-th concave mirror M1−(4n-1) is used for the pointing adjustment.

### 4. Holder

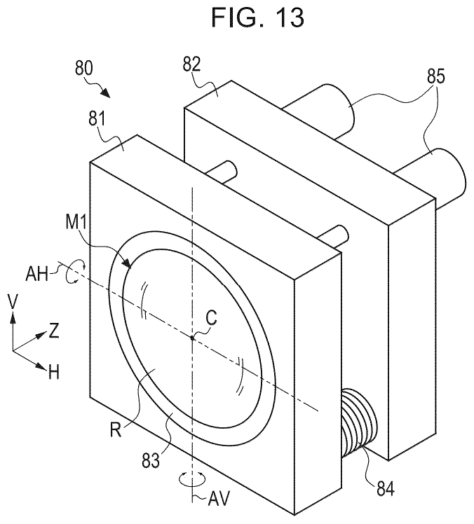

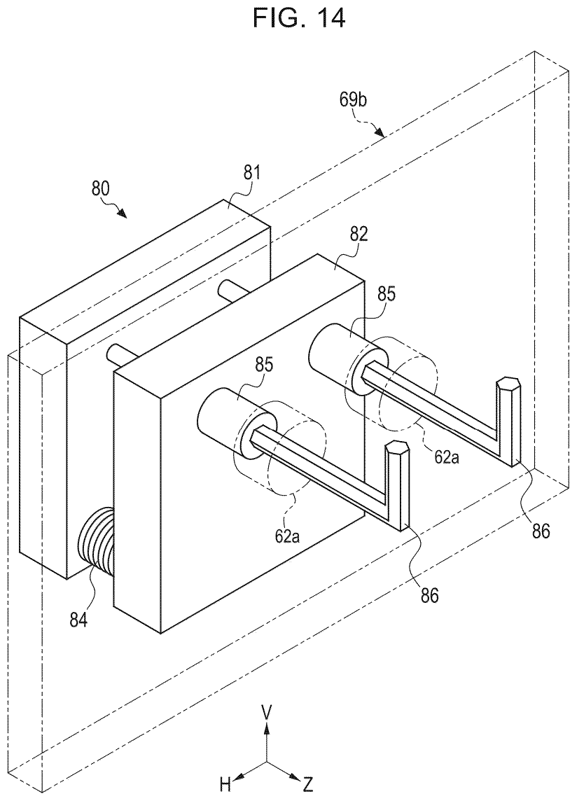

Next, the configuration of a holder 80 that holds each of the concave mirrors M1 used for the positioning adjustment and the pointing adjustment will be described. FIG. 13 is a view of the holder 80 viewing from a front side. FIG. 14 is a view of the holder 80 viewing from a rear side.

The holder 80 includes a pair of holding members 81, 82, a pressing member 83, a plurality of elastic bodies 84, and an angle adjustment device 85. The holder 80 is arranged at an internal space of the housing 69. The pair of holding members 81, 82 are each plate-shaped members and face each other in the Z direction. The concave mirror M1 is attached to the holding member 81. The periphery of a reflection surface R of the concave mirror M1 is pressed against the holding member 81 by the pressing member 83. Each of the plurality of elastic bodies 84 is, for example, a spring, and is arranged between the pair of holding members 81, 82.

The angle adjustment device 85 is, for example, a pair of micrometers, and is attached to the pair of holding members 81, 82. The angle adjustment device 85 is operable from the side cover 69b side. Specifically, the operator can operate the angle adjustment device 85 as passing the operating member 86 such as a hexagonal wrench through the hole 62a of the side cover 69b. The angle adjustment device 85 changes the angle of the holding member 81 with respect to the holding member 82 by expanding and contracting in response to the operation. Thus, the angle of the reflection surface R of the concave mirror M1 is changed.

That is, the concave mirror M1 is arranged such that the angle of the reflection surface R can be changed while the position thereof is fixed by the holder 80. The reflection surface R is rotatable, with the position of the center being fixed, independently around a rotation axis AV passing through the center C and parallel to the V-axis direction and a rotation axis AH passing through the center C and parallel to the H-axis direction. The same applies to the holder that holds the concave mirror M2.

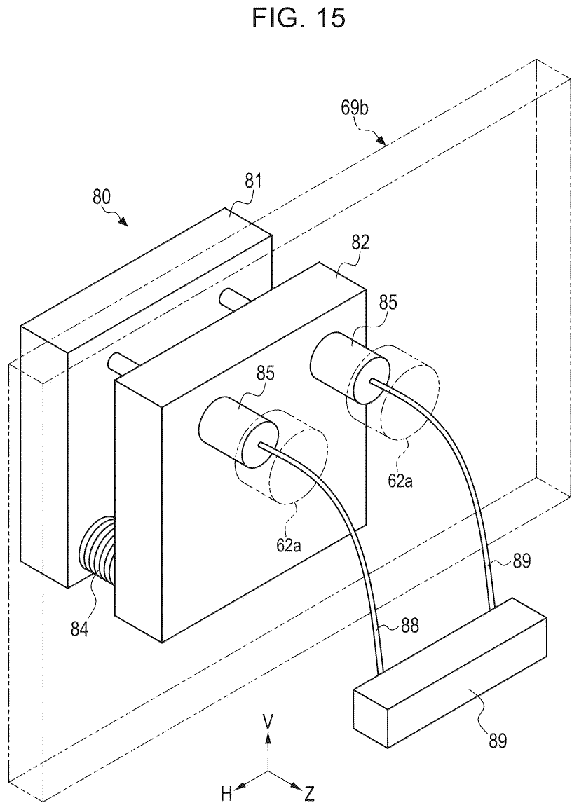

FIG. 15 shows a modification of the angle adjustment device 85. In the present modification, the angle adjustment device 85 is an electric actuator. A drive device 89 is connected to the angle adjustment device 85 via a signal line 88 inserted through the hole 62a of the side cover 69b. The signal line 88 and the drive device 89 may be connected to the angle adjustment device 85 only during the alignment adjustment operation.

A power source (not shown) and a processor (not shown) are connected to the drive device 89, and an operation device (not shown) is connected to the processor. In response to operation of the operation device by the operator, the processor operates the drive device 89. The angle adjustment device 85 changes the angle of the holding member 81 with respect to the holding member 82 by expanding and contracting in response to the operation of the drive device 89. Thus, the angle of the reflection surface R of the concave mirror M1 is changed.

In both of FIGS. 14 and 15, not limited to the side cover 69b, the hole 62a for operating the angle adjustment device 85 may be formed at the front cover 69a. By operating the angle adjustment device 85 through the hole 62a, the alignment adjustment can be performed with the front cover 69a and the side covers 69b, 69c closed.

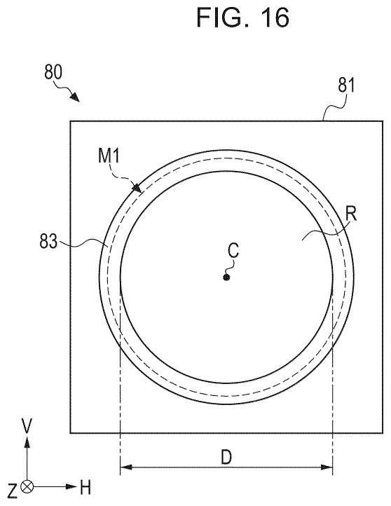

FIG. 16 is a front view of the holder 80. In the reflection surface R of the concave mirror M1, a region exposed out of the pressing member 83 corresponds to a clear aperture. As shown in FIG. 16, the pressing member 83 has a circular ring shape, and the inner diameter of the pressing member 83 corresponds to a clear aperture diameter D.

### 5. Electronic Device Manufacturing Method

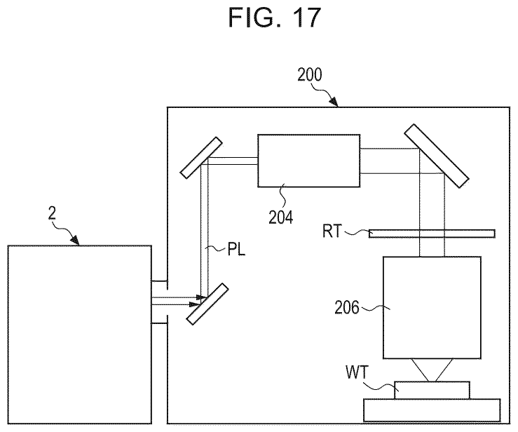

FIG. 17 schematically shows a configuration example of an exposure apparatus 200. The exposure apparatus 200 includes an illumination optical system 204 and a projection optical system 206. For example, the illumination optical system 204 illuminates a reticle pattern of a reticle (not shown) arranged on a reticle stage RT with the pulse laser light PL incident from the laser device 2. The projection optical system 206 causes the pulse laser light PL transmitted through the reticle to be imaged as being reduced and projected on a workpiece (not shown) arranged on a workpiece table WT. The workpiece is a photosensitive substrate such as a semiconductor wafer on which photoresist is applied.

The exposure apparatus 200 synchronously translates the reticle stage RT and the workpiece table WT to expose the workpiece to the pulse laser light PL reflecting the reticle pattern. After the reticle pattern is transferred onto the semiconductor wafer by the exposure process described above, a semiconductor device can be manufactured through a plurality of processes. The semiconductor device is an example of the “electronic device” in the present disclosure.

The description above is intended to be illustrative and the present disclosure is not limited thereto. Therefore, it would be obvious to those skilled in the art that various modifications to the embodiments of the present disclosure would be possible without departing from the spirit and the scope of the appended claims. Further, it would be also obvious to those skilled in the art that the embodiments of the present disclosure would be appropriately combined. The terms used throughout the present specification and the appended claims should be interpreted as non-limiting terms unless clearly described. For example, terms such as “comprise”, “include”, “have”, and “contain” should not be interpreted to be exclusive of other structural elements. Further, indefinite articles “a/an” described in the present specification and the appended claims should be interpreted to mean “at least one” or “one or more”. Further, “at least one of A, B, and C” should be interpreted to mean any of A, B, C, A+B, A+C, B+C, and A+B+C as well as to include combinations of the any thereof and any other than A, B, and C.

What is claimed is:

1. A pulse width extension device comprising:
a beam splitter configured to split pulse laser light into loop light and through light and superimpose the loop light circulated through a loop optical path at least once on the through light; and
a plurality of concave mirrors configuring the loop optical path,
a total number of the concave mirrors being 4n, where n is an integer equal to or more than 1, and
a first concave mirror on which the loop light is incident firstly from the beam splitter and a second concave mirror on which the loop light is incident thirdly or in a 4n-1-th order from the beam splitter, among the plurality of concave mirrors, being arranged such that an angle of a reflection surface of each of the first concave mirror and the second concave mirror is capable of being adjusted with a position thereof fixed.

2. The pulse width extension device according to claim 1,
wherein a first concave mirror group including, among the plurality of concave mirrors, a plurality of concave mirrors on which the loop light is incident each in odd-numbered orders from the beam splitter and a second concave mirror group including, among the plurality of concave mirrors, a plurality of concave mirrors on which the loop light is incident each in even-numbered orders from the beam splitter are arranged at positions facing each other.

3. The pulse width extension device according to claim 2,
wherein, when the second concave mirror is the concave mirror on which the loop light is thirdly incident, area of a reflection surface of a concave mirror, among the plurality of concave mirrors included in the second concave mirror group, on which the loop light is secondly incident is larger than area of the reflection surface of the first concave mirror.

4. The pulse width extension device according to claim 2,
wherein, when the second concave mirror is the concave mirror on which the loop light is incident in a 4n-1-th order, area of a reflection surface of each concave mirror other than a concave mirror, among the plurality of concave mirrors included in the second concave mirror group, on which the loop light is lastly incident is larger than area of the reflection surface of the first concave mirror.

5. The pulse width extension device according to claim 1,
wherein positioning of the loop light is adjusted by changing the angle of the reflection surface of the first concave mirror.

6. The pulse width extension device according to claim 5,
wherein pointing of the loop light is adjusted by changing the angle of the reflection surface of the second concave mirror.

7. The pulse width extension device according to claim 1,
wherein each of the first concave mirror and the second concave mirror is held by a holder that allows the angle of the reflection surface thereof to be changed with a center position thereof fixed.

8. The pulse width extension device according to claim 7,
wherein the holder is arranged at an internal space of a housing, and includes an angle adjustment device configured to change the angle of the reflection surface.

9. The pulse width extension device according to claim 8,
wherein the housing is formed with one or more holes that allow the angle adjustment device to be operated.

10. The pulse width extension device according to claim 1,
wherein the beam splitter reflects a part of the pulse laser light to generate the loop light, and transmits another part of the pulse laser light to generate the through light.

11. A laser device comprising:
the pulse width extension device according to claim 1; and
a laser oscillator configured to output the pulse laser light.

12. An alignment adjustment method of a pulse width extension device, comprising:
changing an angle of a reflection surface of a first concave mirror; and
changing an angle of a reflection surface of a second concave mirror,
the pulse width extension device including:
a beam splitter configured to split pulse laser light into loop light and through light and superimpose the loop light circulated through a loop optical path at least once on the through light; and
a plurality of concave mirrors configuring the loop optical path,
a total number of the concave mirrors being 4n, where n is an integer equal to or more than 1, and
the first concave mirror on which the loop light is incident firstly from the beam splitter and the second concave mirror on which the loop light is incident thirdly or in a 4n-1-th order from the beam splitter, among the plurality of concave mirrors, being arranged such that the angle of the reflection surface of each of the first concave mirror and the second concave mirror is capable of being adjusted with a position thereof fixed.

13. An electronic device manufacturing method, comprising:
generating pulse laser light with a pulse width extended using a laser device;
outputting the pulse laser light to an exposure apparatus; and
exposing a photosensitive substrate to the pulse laser light in the exposure apparatus to manufacture an electronic device,
the laser device including:
a laser oscillator configured to output the pulse laser light; and
a pulse width extension device in which the pulse laser light having entered is output with the pulse width thereof extended,
the pulse width extension device including:
a beam splitter configured to split the pulse laser light into loop light and through light and superimpose the loop light circulated through a loop optical path at least once on the through light; and
a plurality of concave mirrors configuring the loop optical path,
a total number of the concave mirrors being 4n, where n is an integer equal to or more than 1, and
a first concave mirror on which the loop light is incident firstly from the beam splitter and a second concave mirror on which the loop light is incident thirdly or in a 4n-1-th order from the beam splitter, among the plurality of concave mirrors, being arranged such that an angle of a reflection surface of each of the first concave mirror and the second concave mirror is capable of being adjusted with a position thereof fixed.
